(19) United States
(12) Patent Application Publication
(10) Pub. No.: US 2023/0298951 A1
(43) Pub. Date: Sep. 21, 2023

(54) TEST STRUCTURES FOR A WAFER, AND ASSOCIATED DEVICES, SYSTEMS, AND METHODS

(71) Applicant: Micron Technology, Inc., Boise, ID (US)

(72) Inventors: Chase M. Hunter, Boise, ID (US); Marlon W. Hug, Kuna, ID (US); Stephen W. Russell, Boise, ID (US); Rajesh Kamana, Boise, ID (US); Amitava Majumdar, Boise, ID (US); Radhakrishna Kotti, Meridian, ID (US); Ahmed N. Noemaun, Boise, ID (US); Tejaswi K. Indukuri, Boise, ID (US)

(21) Appl. No.: 17/696,261

(22) Filed: Mar. 16, 2022

(51) Int. Cl. H01L 21/66

(52) U.S. Cl. CPC H01L 22/34; H01L 22/32; H01L 22/12

(57) ABSTRACT

Test structures for wafers are disclosed. A device may include a silicon wafer including a number of die and a scribe area between two die of the number of die. The scribe area may include one or more test structures. The test structures may include a p-doped region and an n-doped region adjacent to the p-doped region. The test structures may also include a first contact electrically coupled to the p-doped region and a second contact electrically coupled to the n-doped region. The second contact may be proximate to the first contact. Associated devices, systems, and methods are also disclosed.

### TECHNICAL FIELD

Embodiments of the disclosure relate to test structures. More specifically, various embodiments relate to test structures for a scribe area of a semiconductor wafer. Additionally, embodiments include related methods, devices, and systems.

### BACKGROUND

Semiconductor devices are often manufactured through a series of process steps performed on a silicon wafer. The process steps may include singulating dice from other dice and/or the wafer. Singulating often involves cutting through (e.g., with a saw) a portion of the wafer to separate dice. The portion of the wafer between dice (and/or surrounding the dice) is commonly known as the scribe area.

A test structure may be used to analyze results of one or more process steps. For example, a test structure may be analyzed after one or more process steps have occurred to determine the quality of the performance of the one or more process steps and/or the quality of dice being produced by the one or more process steps.

### BRIEF DESCRIPTION OF THE SEVERAL VIEWS OF THE DRAWINGS

While this disclosure concludes with claims particularly pointing out and distinctly claiming specific embodiments, various features and advantages of embodiments within the scope of this disclosure may be more readily ascertained from the following description when read in conjunction with the accompanying drawings, in which:

FIG. 1 is a functional block diagram illustrating an example wafer in accordance with at least one embodiment of the disclosure.

FIG. 2 is a perspective view of a diagram illustrating an example test structure in accordance with at least one embodiment of the disclosure.

FIG. 3A is a layout diagram illustrating a top-view of an example test structure in accordance with at least one embodiment of the disclosure.

FIG. 3B is a layout diagram illustrating a side-view of the example test structure of FIG. 3A in accordance with at least one embodiment of the disclosure.

FIG. 4A is a layout diagram illustrating a top-view of another example test structure in accordance with at least one embodiment of the disclosure.

FIG. 4B is a layout diagram illustrating a side-view of the example test structure of FIG. 4A in accordance with at least one embodiment of the disclosure.

FIG. 5A is a layout diagram illustrating a top-view of yet another example test structure in accordance with at least one embodiment of the disclosure.

FIG. 5B is a layout diagram illustrating a side-view of the example test structure of FIG. 5A in accordance with at least one embodiment of the disclosure.

FIG. 6 is an illustration of an example reflection profile of a test structure according to at least one embodiment of the disclosure.

FIG. 7 is an illustration of an example reflection profile of a test structure according to at least one embodiment of the disclosure.

FIG. 8 is a flowchart illustrating an example method in accordance with at least one embodiment of the disclosure.

FIG. 9 is a functional block diagram illustrating an example system in accordance with at least one embodiment of the disclosure.

### DETAILED DESCRIPTION

As noted above, semiconductor devices are often manufactured through a series of process steps that may include singulating dice from other dice and/or a semiconductor wafer. Further, as noted above, a test structure may be analyzed after one or more process steps to determine the quality of the performance of the one or more process steps and/or the quality of dice being produced by the one or more process steps.

Some embodiments of this disclosure include a test structure that may be included in a scribe area of a wafer. The test structure in the scribe area may be analyzed between process steps and before singulation of dice. Other embodiments include a similar or analogous test structure that may be included in one or more dice of a wafer.

A test structure may be analyzed following one or more process steps to determine, among other things, quality of the performance of the process steps. The quality of the performance of the process steps may be indicative of a quality of the dice being produced by the process steps. For example, if a test structure exhibits voltage leakage between two areas of the test structure that are designed to be electrically isolated (e.g., voltage leakage between two contacts (e.g., contact-to-contact leakage)), the dice may exhibit voltage leakage in analogous structures of the dice.

Some embodiments of this disclosure include a test structure including a first contact electrically coupled to a p-type diffusion region adjacent to a second contact electrically coupled to an n-type diffusion region (e.g., there may be a buffer region between the p-type diffusion region and the n-type diffusion region). If the test structure exhibits voltage leakage (e.g., between the p-type diffusion region and the n-type diffusion region), the second contact may have a higher reflectivity when impinged by an electron beam than if the test structure does not exhibit voltage leakage. Thus, one or more test structures may be included on a wafer and the test structures may be analyzed (e.g., using electron-beam testing) to analyze a quality of performance of one or more process steps and/or a quality of one or more dice (e.g., dice on the same wafer as the test structure).

In some embodiments, a test structure may include multiple first contacts electrically coupled to one or more p-type diffusion regions, each of the one or more p-type diffusion regions adjacent to a respective n-type diffusion region, each of the n-type diffusion regions electrically coupled to one or more second contacts. For example, the test structure may include multiple p-type diffusion regions alternatingly arranged with multiple n-type diffusion regions. The test structure may include a grid of first contacts arranged electrically coupled to the multiple p-type diffusion regions and a grid of second contacts electrically coupled to the multiple n-type diffusion regions. The first contacts and the second contacts may be arranged in pairs e.g., each of the first contacts may be proximate to one of the second contacts. Thus, if the whole test structure is impinged (e.g., scanned) with an electron beam, a ratio of second contacts exhibiting high reflectivity may be determined. The ratio may be indicative of a quality of performance of process steps and/or a quality of one or more dice. Embodiments of the disclosure will now be explained with reference to the accompanying drawings.

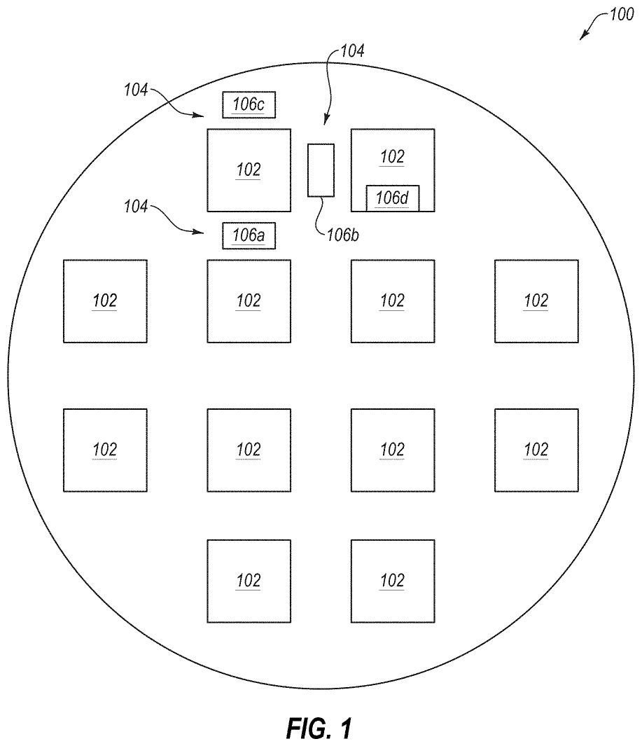

FIG. 1 is a functional block diagram illustrating an example wafer 100 in accordance with at least one embodiment of the disclosure. Wafer 100 includes dice 102 and scribe area 104 surrounding and between dice 102. As used herein, and with regard to wafer 100 bearing unsingulated dice, the terms “die” and “dice” include unsingulated die locations on a wafer, laterally separated by a scribe area. The scribe area between the die locations is also referred to in the industry as “streets.” Wafer 100 includes multiple test structures 106 as examples of locations in which test structures may be placed on a wafer.

Test structure 106a, test structure 106b, test structure 106c, and test structure 106d may be referred to collectively as test structures 106. Test structures 106 are arranged at various example locations on wafer 100. In various embodiments, a wafer may include any number of test structures 106 arranged in any number of locations. For example, test structure 106a is illustrated between two dice 102, test structure 106b is illustrated between two dice 102, test structure 106c is illustrated in the scribe area 104 surrounding dice 102 and not between any of dice 102, and test structure 106d is illustrated on or within one die 102. Embodiments of this disclosure may include any number of test structures 106 arranged anywhere on wafer 100.

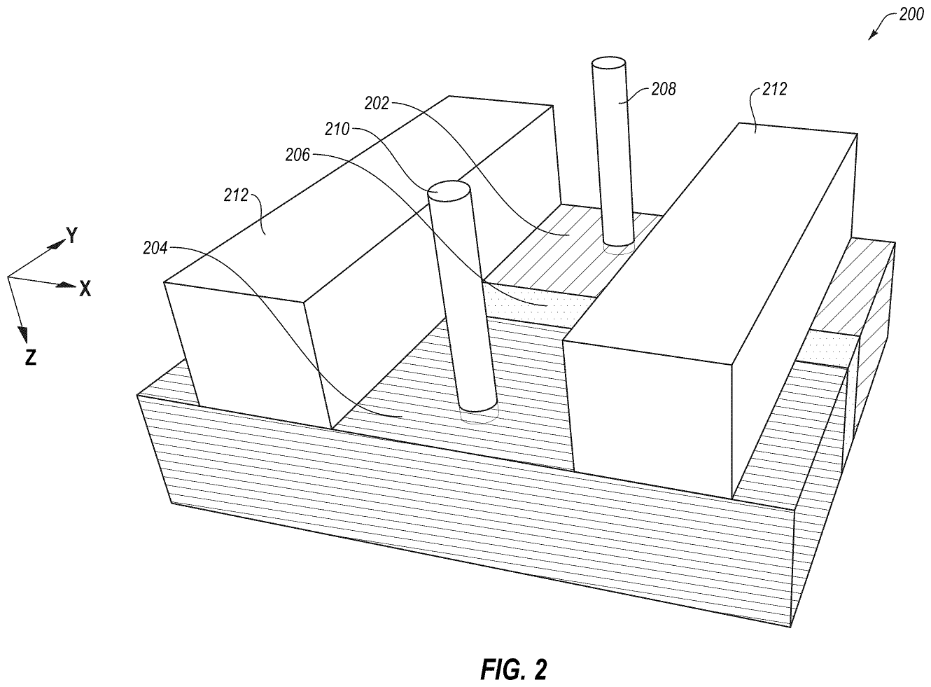

FIG. 2 is a perspective view of a diagram illustrating an example test structure 200 in accordance with at least one embodiment of the disclosure. For example, any of test structures 106 of FIG. 1 may be, or may include, test structure 200. Test structure 200 includes a p-type diffusion region 202 adjacent to an n-type diffusion region 204. Test structure 200 includes a buffer region 206 between p-type diffusion region 202 and n-type diffusion region 204. Test structure 200 includes a contact 208 electrically coupled to p-type diffusion region 202 and a contact 210 electrically coupled to n-type diffusion region 204. Test structure 200 is also illustrated including contact buffers 212. Contact buffers 212 are optional.

P-type diffusion region 202 may be a p-doped region of a semiconductor material (e.g., silicon). For example, p-type diffusion region 202 may be a region of a substrate (e.g., a silicon substrate) (not illustrated in FIG. 2) doped with any suitable p-type dopant e.g., boron.

N-type diffusion region 204 may be an n-doped region of a semiconductor material. For example, n-type diffusion region 204 may be a region of the substrate doped with any suitable n-type dopant e.g., phosphorus.

P-type diffusion region 202 may be adjacent to n-type diffusion region 204. Further, p-type diffusion region 202 may be separated from n-type diffusion region 204 by buffer region 206. Buffer region 206 may be, or may include, a portion of the substrate on or in which p-type diffusion region 202 and n-type diffusion region 204 are formed. For example, buffer region 206 may be a portion of the substrate that is not doped while p-type diffusion region 202 and n-type diffusion region 204 are doped.

In some embodiments, the substrate and/or buffer region 206 may be neutral e.g., undoped silicon or type-IV-doped silicon. In such embodiments, a p-well may be under p-type diffusion region 202 and n-type diffusion region 204. For example, a p-well may partially surround p-type diffusion region 202 and n-type diffusion region 204. For example, the p-well may separate p-type diffusion region 202 and n-type diffusion region 204 from the undoped substrate. In other embodiments, the substrate may be p-doped. The degree and/or type of p-type doping of p-type diffusion region 202 may be different than or the same as the degree and/or type of p-type doping of the substrate or the p-well.

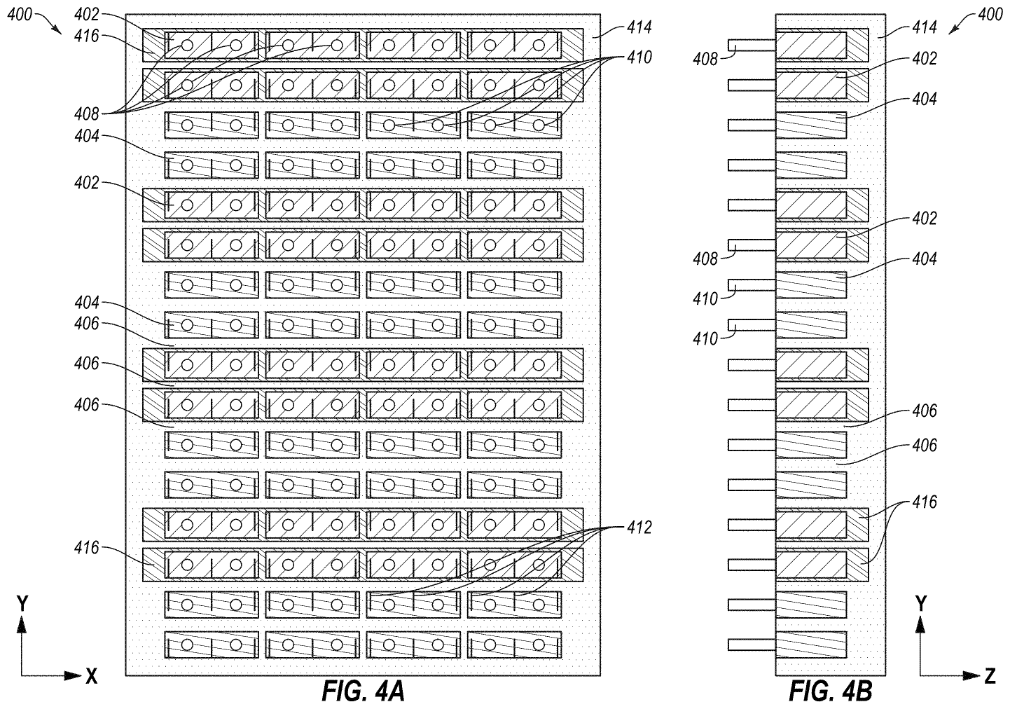

In some embodiments, an n-well (not illustrated in FIG. 2) may be under p-type diffusion region 202. In some embodiments, the n-well may partially surround p-type diffusion region 202. For example, the n-well may separate p-type diffusion region 202 from the substrate (which, in some embodiments, may be p-doped) or the p-well under p-type diffusion region 202. The degree and/or type of n-type doping of n-type diffusion region 204 may be different than or the same as the degree and/or type of n-type doping of the n-well. Additional detail regarding an embodiment including an n-well under p-type diffusion region 202 is illustrated in and described with regard to FIG. 4A and FIG. 4B.

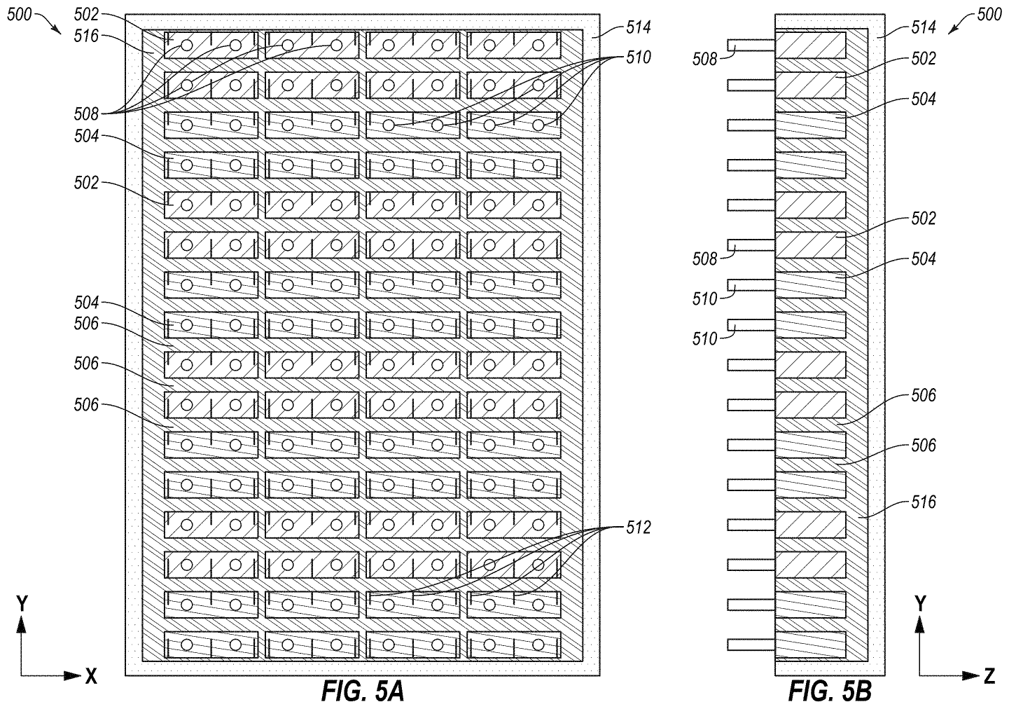

In some embodiments, an n-well may be under n-type diffusion region 204. In some embodiments, the n-well may partially surround n-type diffusion region 204. For example, the n-well may separate n-type diffusion region 204 from the substrate or the p-well. The n-well under n-type diffusion region 204 may be the same n-well that is under p-type diffusion region 202. Additional detail regarding an embodiment including an n-well under p-type diffusion region 202 and n-type diffusion region 204 is illustrated in and described with regard to FIG. 5A and FIG. 5B.

Contact 208 and contact 210 may be formed of any suitable electrically conductive material e.g., tungsten. Contact 208 may be substantially the same as contact 210, the difference being that contact 208 may be electrically coupled to p-type diffusion region 202 whereas contact 210 is electrically coupled to n-type diffusion region 204. Contact 208 and contact 210 may be a pair of contacts. For example, contact 208 may be proximate to contact 210 or contact 208 may be closer to contact 210 than contact 208 is to another contact.

Test structure 200 may be such that if test structure 200 does not exhibit voltage leakage (e.g., from p-type diffusion region 202 to n-type diffusion region 204 or vice versa) and test structure 200 is impinged by an electron beam (e.g., during an electron-beam test), contact 208 may reflect electrons and contact 210 may reflect fewer electrons than reflected by contact 208. This may be because a contact electrically coupled to a p-type diffusion region may prevent electrons from an electron beam to transfer into an n-well or into the substrate while a contact electrically coupled to an n-type diffusion region may allow electrons from (or allow fewer electrons to (compared with the contact electrically coupled to the p-type diffusion region)) transfer into the substrate or into a p-well. Thus, the contact electrically coupled to the p-type diffusion region may reflect more electrons than the contact electrically coupled to the n-type diffusion region.

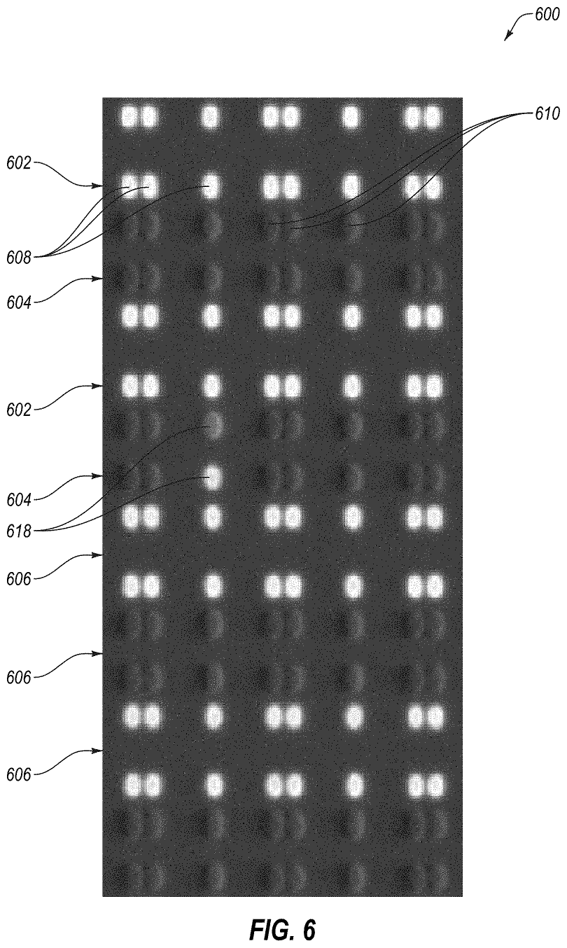

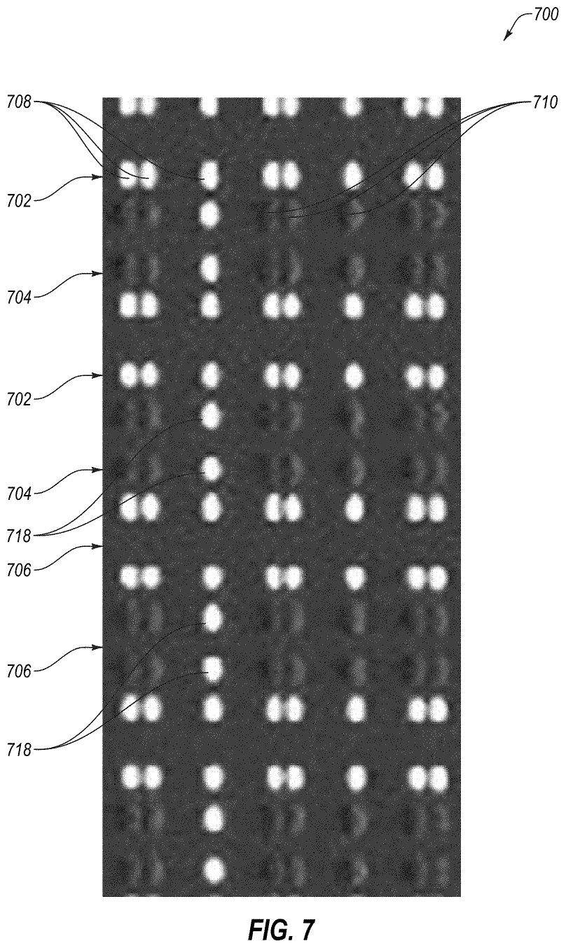

Further, test structure 200 may be such that if test structure 200 exhibits voltage leakage (e.g., from p-type diffusion region 202 to n-type diffusion region 204 or vice versa) and test structure 200 were impinged by an electron beam, contact 210 may reflect more electrons than would be reflected if test structure 200 did not exhibit voltage leakage. This may be because in the case of voltage leakage, an n-type diffusion region may behave more like a p-type diffusion region. For example, an n-type diffusion region exhibiting voltage leakage may allow more electrons to transfer into the substrate. Thus, a contact electrically coupled to a leaking n-type diffusion region may have a higher reflectivity than a contact electrically coupled to an n-type diffusion region that does not exhibit voltage leakage. FIG. 6 and FIG. 7, which are described more fully below, illustrate outputs of electron beam testing of a test structure. The outputs shown in FIG. 6 and FIG. 7 exhibit some contacts that exhibit low reflectivity (e.g., as a result of the contacts not exhibiting voltage leakage) and some contacts that exhibit higher reflectivity (e.g., as a result of the contacts exhibiting voltage leakage).

Some embodiments of test structures may include contact buffers 212. Other embodiments (not illustrated in FIG. 2) of test structures may not include contact buffers 212. Contact buffers 212 may be any suitable insulative material, e.g., polysilicon. Contact buffers 212 may be positioned between contacts. For example, contact buffers 212 may be positioned between contact 208 and another contact (not illustrated in FIG. 2) e.g., positioned to the right or left of contact 208 electrically coupled to p-type diffusion region 202 and/or between contact 210 and another contact (not illustrated in FIG. 2) e.g., positioned to the right or left of contact 210 electrically coupled to n-type diffusion region 204. Contact buffers 212 may prevent (or lessen effects of) capacitive coupling between contacts (e.g., between adjacent contacts 208 and/or adjacent contacts 210).

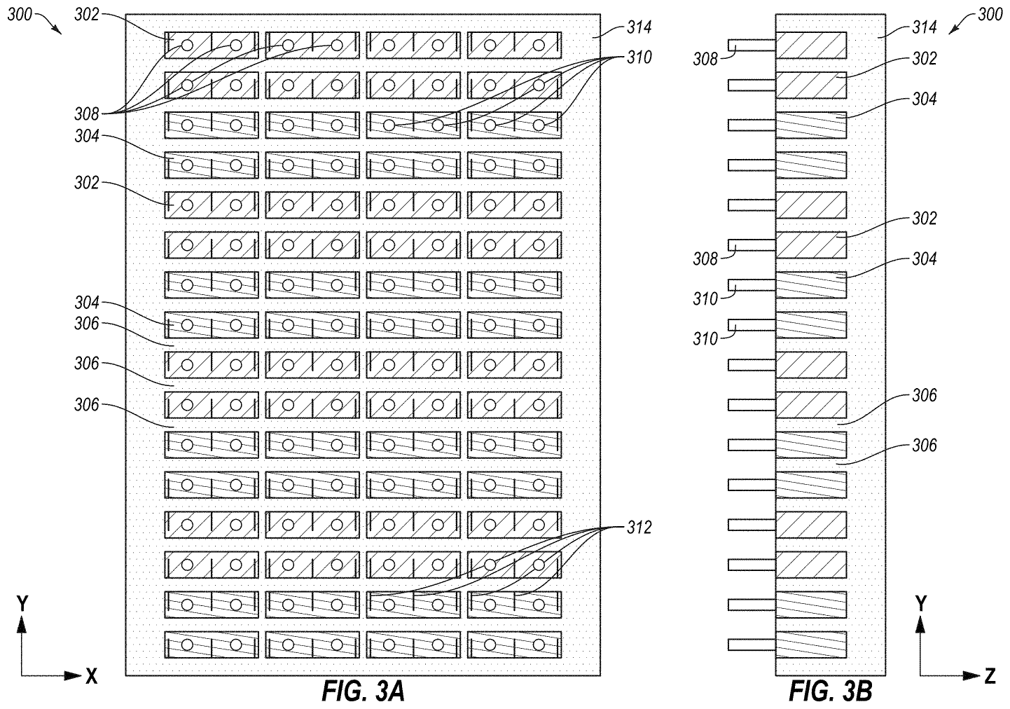

FIG. 3A is a layout diagram illustrating a top-view of an example test structure 300 in accordance with at least one embodiment of the disclosure. FIG. 3B is a layout diagram illustrating a side-view of the example test structure 300 of FIG. 3A in accordance with at least one embodiment of the disclosure. For example, any of test structures 106 of FIG. 1 may be, or may include, test structure 300.

Test structure 300 includes p-type diffusion regions 302, each of which may be an example of a p-type diffusion region 202 of FIG. 2. P-type diffusion regions 302 may extend in a first direction (e.g., the x-direction as illustrated with regard to FIG. 3A).

Test structure 300 includes n-type diffusion regions 304 each of which may be an example of n-type diffusion region 204 of FIG. 2. N-type diffusion regions 304 may extend in the first direction. N-type diffusion regions 304 may be alternatingly arranged with p-type diffusion regions 302. In other words, n-type diffusion regions 304 may run alongside (and/or between) p-type diffusion regions 302.

P-type diffusion regions 302 may be separated from n-type diffusion regions 304 by buffer regions 306. Each of buffer regions 306 may be an example of buffer region 206 of FIG. 2. Buffer regions 306 may be a portion of substrate 314.

Each of p-type diffusion regions 302 may be electrically coupled to one or more of contacts 308. For example, as illustrated in FIG. 3A, each of p-type diffusion regions 302 may be electrically coupled to multiple contacts 308 distributed in the first direction.

Each of n-type diffusion regions 304 may be electrically coupled to one or more of contacts 310. For example, as illustrated in FIG. 3A, each of n-type diffusion regions 304 may be electrically coupled to multiple contacts 310 distributed in the first direction.

Each of contacts 308 may be paired with a corresponding one of contacts 310. The pairing may be based on proximity. For example, one of contacts 308 may be paired with one of contacts 310 closest to the one of contacts 308. Each of contacts 308 may be aligned in the first direction with a corresponding one of contacts 310.

In some embodiments, as illustrated in FIG. 3A and FIG. 3B, each of p-type diffusion regions 302 may include two rows of contacts 308 e.g., each proximate to a corresponding row of contacts 310 on a corresponding adjacent one of n-type diffusion regions 304. In such embodiments, each of p-type diffusion regions 302 may be divided by a respective one of buffer regions 306. Similarly, each of n-type diffusion regions 304 may include two rows of contacts 310 e.g., each proximate to a corresponding row of contacts 308 on a corresponding adjacent one of p-type diffusion regions 302. In such embodiments, each of n-type diffusion regions 304 may be divided by a respective one of buffer regions 306.

Test structure 300 may or may not include contact buffers 312. In other words, contact buffers 312 are optional in test structure 300. Contact buffers 312 may be arranged to separate each of contacts 308 from adjacent ones of contacts 308. Additionally or alternatively, contact buffers 312 may be arranged to separate each of contacts 310 from adjacent ones of contacts 310. Contact buffers 312 may be an example of contact buffers 212 of FIG. 2.

Test structure 300 includes a substrate 314, or test structure 300 is formed on or in substrate 314. In FIG. 3A, substrate 314 is illustrated extending beyond the extent of p-type diffusion regions 302 and n-type diffusion regions 304 for illustrative purposes i.e., such that substrate 314 is visible in FIG. 3A.

The respective numbers of p-type diffusion regions 302, n-type diffusion regions 304, buffer regions 306, contacts 308, contacts 310, and contact buffers 312 illustrated in FIG. 3A and FIG. 3B are used for illustrative purposes. Other numbers of p-type diffusion regions 302, n-type diffusion regions 304, buffer regions 306, contacts 308, contacts 310, and/or contact buffers 312 may be used in other embodiments.

FIG. 4A is a layout diagram illustrating a top-view of another example test structure 400 in accordance with at least one embodiment of the disclosure. FIG. 4B is a layout diagram illustrating a side-view of the example test structure 400 of FIG. 4A in accordance with at least one embodiment of the disclosure. For example, any of test structures 106 of FIG. 1 may be, or may include, test structure 400.

P-type diffusion regions 402 may be substantially the same as p-type diffusion regions 302 of FIG. 3A and FIG. 3B. N-type diffusion regions 404 may be substantially the same as n-type diffusion regions 304 of FIG. 3A and FIG. 3B. Buffer regions 406 may be substantially the same as buffer regions 306 of FIG. 3A and FIG. 3B. Contacts 408 may be substantially the same as contacts 308 of FIG. 3A and FIG. 3B. Contacts 410 may be substantially the same as contacts 310 of FIG. 3A and FIG. 3B. Contact buffers 412 may be substantially the same as contact buffers 312 of FIG. 3A and FIG. 3B. As with contact buffers 312 of test structure 300, contact buffers 412 are optional in test structure 400. Substrate 414 may be substantially the same as substrate 314 of FIG. 3A and FIG. 3B.

A difference between test structure 400 and test structure 300 of FIG. 3A and FIG. 3B is that test structure 400 includes n-wells 416. Each of n-wells 416 may be under and/or may partially surround a respective one of p-type diffusion regions 402.

In some embodiments, as illustrated in FIG. 4A and FIG. 4B, there may be a portion of buffer regions 406 between n-wells 416 partially surrounding adjacent portions of p-type diffusion regions 402. For example, a portion of buffer regions 406 may divide each of p-type diffusion regions 402 and one of buffer regions 406 may partially surround each portion of p-type diffusion regions 402. In other embodiments (not illustrated in FIG. 4A and FIG. 4B) a single one of n-wells 416 may partially surround adjacent portions of p-type diffusion regions 402. In such embodiments, a portion of each of n-wells 416 may divide portions of p-type diffusion regions 402.

Test structure 400 includes a substrate 414, or test structure 400 is formed on or in substrate 414. In FIG. 4A, substrate 414 is illustrated extending beyond the extent of p-type diffusion regions 402 and n-type diffusion regions 404 for illustrative purposes. Likewise, n-wells 416 are illustrated extending beyond the extent of p-type diffusion regions 402 for illustrative purposes.

The respective numbers of p-type diffusion regions 402, n-type diffusion regions 404, buffer regions 406, contacts 408, contacts 410, and contact buffers 412 illustrated in FIG. 4A and FIG. 4B are used for illustrative purposes. Other numbers of p-type diffusion regions 402, n-type diffusion regions 404, buffer regions 406, contacts 408, contacts 410, and/or contact buffers 412 may be used in other embodiments.

FIG. 5A is a layout diagram illustrating a top-view of yet another example test structure 500 in accordance with at least one embodiment of the disclosure. FIG. 5B is a layout diagram illustrating a side-view of the example test structure 500 of FIG. 5A in accordance with at least one embodiment of the disclosure. For example, any of test structures 106 of FIG. 1 may be, or may include, test structure 500.

P-type diffusion regions 502 may be substantially the same as p-type diffusion regions 302 of FIG. 3A and FIG. 3B. N-type diffusion regions 504 may be substantially the same as n-type diffusion regions 304 of FIG. 3A and FIG. 3B. Contacts 508 may be substantially the same as contacts 308 of FIG. 3A and FIG. 3B. Contacts 510 may be substantially the same as contacts 310 of FIG. 3A and FIG. 3B. Contact buffers 512 may be substantially the same as contact buffers 312 of FIG. 3A and FIG. 3B. As with contact buffers 312 of test structure 300, contact buffers 512 are optional in test structure 500. Substrate 514 may be substantially the same as substrate 314 of FIG. 3A and FIG. 3B.

A difference between test structure 500 and test structure 300 of FIG. 3A and FIG. 3B is that test structure 500 includes an n-well 516. N-well 516 may be under and/or may partially surround multiple ones of p-type diffusion regions 502 and n-type diffusion regions 504.

Another difference between test structure 500 and test structure 300 of FIG. 3A and FIG. 3B is that in test structure 500, buffer regions 506 may be comprised of a substrate 514. In other words, portions of n-well 516 may separate p-type diffusion regions 502 from n-type diffusion regions 504. Further, portions of n-well 516 may divide portions of p-type diffusion regions 502 and portions of n-well 516 may divide portions of n-type diffusion regions 504.

Test structure 500 includes substrate 514, or test structure 500 is formed on or in substrate 514. In FIG. 5A, substrate 514 is illustrated extending beyond the extent of p-type diffusion regions 502 and n-type diffusion regions 504 for illustrative purposes. Likewise, in FIG. 5A, n-well 516 is illustrated as extending beyond the extent of p-type diffusion regions 502 and n-type diffusion regions 504 for illustrative purposes.

The respective numbers of p-type diffusion regions 502, n-type diffusion regions 504, buffer regions 506, contacts 508, contacts 510, and contact buffers 512 illustrated in FIG. 5A and FIG. 5B are used for illustrative purposes. Other numbers of p-type diffusion regions 502, n-type diffusion regions 504, buffer regions 506, contacts 508, contacts 510, and/or contact buffers 512 may be used in other embodiments.

FIG. 6 is an illustration of an example reflection profile 600 of a test structure according to at least one embodiment of the disclosure. For example, reflection profile 600 is an example of an output of an electron-beam scan of an example test structure of this disclosure.

Reflection profile 600 illustrates reflections that may be obtained from contacts 608 electrically coupled to p-type diffusion regions 602 and from contacts 610 electrically coupled to n-type diffusion regions 604.

Reflections from contacts 608 may be bright (i.e., exhibit high reflectivity) relative to reflections from n-type diffusion regions 604 and relative to reflections from the substrate, p-well, or n-well. Reflections from contacts 608 may be bright because contacts electrically coupled to p-type diffusion regions may allow electrons from an electron beam to transfer into n-wells or into the substrate. Thus, contacts electrically coupled to p-type diffusion regions may reflect electrons of the electron beam. Reflections from most of the n-type diffusion regions 604 may be dark (i.e., exhibit low reflectivity) compared to reflections from p-type diffusion regions 602. This may be because contacts electrically coupled to n-type diffusion regions may prevent electrons from (or allow fewer electrons to (compared with contacts electrically coupled to p-type diffusion regions)) transfer into the substrate or into a p-well. Thus, contact electrically coupled to the n-type diffusion regions may reflect fewer electrons than contacts electrically coupled to p-type diffusion regions.

However, contacts 618, which are among contacts 610 electrically coupled to n-type diffusion regions 604, may appear bright i.e., brighter than others of contacts 610. Contacts 618 may appear bright because there may be voltage leakage e.g., between one or more of p-type diffusion regions 602 and one or more of n-type diffusion regions 604. For example, there may be voltage leakage between one of the p-type diffusion regions 602 adjacent to the one of n-type diffusion regions 604 to which contacts 618 are electrically coupled and the one of n-type diffusion regions 604 to which contacts 618 are electrically coupled. Reflections from contacts 618 may be bright, compared with reflections from the others of contacts 610 because in the case of voltage leakage, an n-type diffusion region behaves more like a p-type diffusion region. For example, an n-type diffusion region exhibiting voltage leakage may allow more electrons to transfer into the substrate. Thus, a contact electrically coupled to a leaking n-type diffusion region may have a higher reflectivity than a contact electrically coupled to an n-type diffusion region that does not exhibit voltage leakage.

Reflection profile 600 may be used to determine a quality of one or more process steps and/or a quality of one or more die. For example, a count of a number of contacts 610 (electrically coupled to n-type diffusion regions 604) that are reflective (e.g., as compared with others of the contacts 610 (or with an expected reflectivity)) may be compared with a count of a number of contacts 610 that exhibit an expected reflectivity. The ratio of reflective contacts 610 to contacts 610 exhibiting expected reflectivity may be indicative of a quality of one or more process steps that generate the test structure and/or of the quality of dice on the same wafer as the test structure. For example, a high ratio of reflective contacts 610 may indicate a high degree of voltage leakage in the test area that may indicate poor quality process steps and/or poor quality dice in the wafer of the test structure.

FIG. 7 is an illustration of an example reflection profile 700 of a test structure according to at least one embodiment of the disclosure. For example, reflection profile 700 is an example of an output of an electron-beam scan of an example test structure of this disclosure.

Reflection profile 700 may be substantially the same as reflection profile 600 of FIG. 6. For example, p-type diffusion regions 702 may be substantially the same as p-type diffusion regions 602 of FIG. 6. N-type diffusion regions 704 may be substantially the same as n-type diffusion regions 604 of FIG. 6. Buffer regions 706 may be substantially the same as buffer regions 606 of FIG. 6. Contacts 708 may be substantially the same as contacts 608 of FIG. 6. Contacts 710 may be substantially the same as contacts 610 of FIG. 6.

A difference between reflection profile 700 and reflection profile 600 is that in reflection profile 700, a row of contacts 710, i.e., contacts 718, all exhibit voltage leakage. A row exhibiting voltage leakage may be indicative of a specific issue with the process and/or dice of the wafer. For example, a row exhibiting voltage leakage may be indicative of a short. For example, a row exhibiting voltage leakage may be indicative that a metallization process (e.g., tungsten deposition) unexpectedly filled a linear seam or void with metal resulting in a unintended electrical paths between two or more elements of the die.

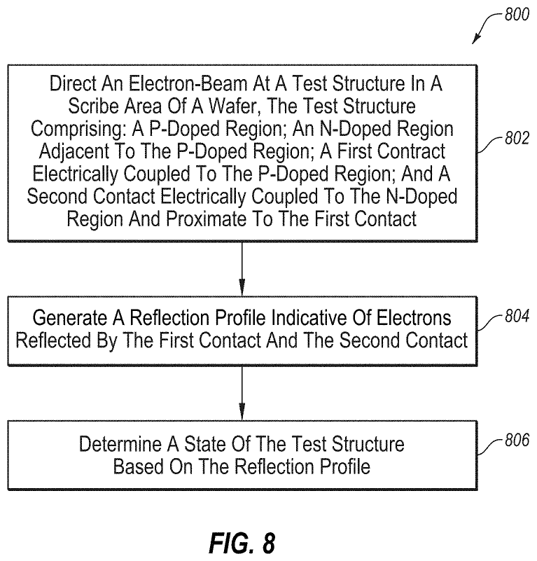

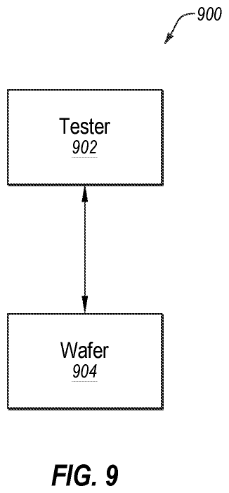

FIG. 8 is a flowchart illustrating an example method 800 in accordance with at least one embodiment of the disclosure. Method 800 may be arranged in accordance with at least one embodiment described in the disclosure. Method 800 may be performed, in some embodiments, by a device or system, such as tester 902 of FIG. 9, or another device or system. Method 800 may be performed on a wafer including one or more test structures, as disclosed herein. For example, method 800 may be performed on any or all of wafer 100 of FIG. 1, test structures 106 of FIG. 1, test structure 200 of FIG. 2, test structure 300 of FIG. 3A and FIG. 3B, test structure 400 of FIG. 4A and FIG. 4B, test structure 500 of FIG. 5A and FIG. 5B, or another wafer or test structure. Although illustrated as discrete blocks, various blocks may be divided into additional blocks, combined into fewer blocks, or eliminated, depending on the desired implementation.

At block 802, an electron-beam may be directed at a test structure. The test structure may be in a scribe area of a wafer e.g., as illustrated by test structure 106a of FIG. 1, test structure 106b of FIG. 1, and test structure 106c of FIG. 1. Additionally or alternatively, the test structure may be in or on a die e.g., as illustrated by test structure 106d of FIG. 1.

At block 802, a field of view may be selected that relates to the size of the test structure. For example, the field of view may be close to, or the same as, the size of the test structure. A field of view that is close to or the same size as the test structure may allow for better throughput of the recipe and/or lower risk of negatively affecting regions outside of the test structure and e.g., regions in the live die.

The test structure may include a p-doped region (e.g., one or more of p-type diffusion region 202 of FIG. 2, one or more of p-type diffusion regions 302 of FIG. 3A and FIG. 3B, one or more of p-type diffusion regions 402 of FIG. 4A and FIG. 4B, and one or more of p-type diffusion regions 502 of FIG. 5A and FIG. 5B). The test structure may also include an n-doped region adjacent to the p-doped region (e.g., one or more of n-type diffusion region 204 of FIG. 2, one or more of n-type diffusion regions 304 of FIG. 3A and FIG. 3B, one or more of n-type diffusion regions 404 of FIG. 4A and FIG. 4B, and one or more of n-type diffusion regions 504 of FIG. 5A and FIG. 5B). The test structure may also include a first contact electrically coupled to the p-doped region (e.g., one or more of contact 208 of FIG. 2, one or more of contacts 308 of FIG. 3A and FIG. 3B, one or more of contacts 408 of FIG. 4A and FIG. 4B, and one or more of contacts 508 of FIG. 5A and FIG. 5B). The test structure may also include a second contact electrically coupled to the n-doped region and proximate to the first contact (e.g., one or more of contact 210 of FIG. 2, one or more of contacts 310 of FIG. 3A and FIG. 3B, one or more of contacts 410 of FIG. 4A and FIG. 4B, and one or more of contacts 510 of FIG. 5A and FIG. 5B).

At block 804, a reflection profile indicative of electrons reflected by the first contact and the second contact may be generated. Reflection profile 600 of FIG. 6 and reflection profile 700 of FIG. 7 are examples of reflection profiles that may be generated at block 804.

At block 806, a state of the test structure may be determined based on the reflection profile. For example, the second contact may be one of multiple second contacts electrically coupled to n-doped regions paired with multiple corresponding first contacts electrically coupled to p-doped regions. A ratio of second contacts that exhibit reflectivity to second contacts that do not exhibit reflectivity may be determined. Based on the ratio, a state of the test structure may be determined. The state of the test structure may be indicative of a degree or amount of voltage leakage exhibited by the test structure. For example, the state of the test structure may be indicative of an error rate. For example, the state of the test structure may be indicative of a quality of one or more process steps that occurred in the creation of the test structure. Additionally or alternatively, the state of the test structure may be indicative of a quality of one or more dice on the same wafer as the test structure.

Some embodiments include determining that the test structure exhibits a contact-to-contact leak responsive to a count of electrons reflected by the second contact exceeding a threshold or determining that the test structure does not exhibit the contact-to-contact leak responsive to the count not exceeding the threshold.

Some embodiments include determining that a process step needs to adjusted and/or that one or more wafers is defective responsive to a count of electrons reflected by a number of second contacts exceeding a threshold or responsive to a count of second contacts that exhibit reflectivity exceeding a threshold.

Modifications, additions, or omissions may be made to method 800 without departing from the scope of the disclosure. For example, the operations of method 800 may be implemented in differing order. Furthermore, the outlined operations and actions are only provided as examples, and some of the operations and actions may be optional, combined into fewer operations and actions, or expanded into additional operations and actions without detracting from the essence of the disclosed embodiment.

FIG. 9 is a functional block diagram illustrating an example system 900 in accordance with at least one embodiment of the disclosure. System 900 includes tester 902 which may include an electron-beam test apparatus including an electron-beam generator, an electron-beam-reflection receiver, and an analyzer. Tester 902 may analyze wafer 904 using an electron beam, e.g., by scanning wafer 904 with the electron beam and generating a reflection profile. Wafer 904 may be an example of wafer 100 of FIG. 1, e.g., including one or more test structures 106 of FIG. 1. Tester 902 may perform one or more of the operations described above with regard to method 800 of FIG. 8 e.g., including generating a reflection profile. Reflection profile 600 of FIG. 6 and reflection profile 700 of FIG. 7 may be examples of reflection profiles that may be generated by tester 902.

Tester 902 may be configured with a field of view that relates to the size of the test structure. For example, the field of view may be close to, or the same as, the size of the test structure. A field of view that is close to or the same size as the test structure may allow for better throughput of the recipe and/or lower risk of negatively affecting regions outside of the test structure and e.g., regions in the live die.

Some embodiments of the present disclosure include a device including a silicon wafer. The silicon wafer may include a number of die and a scribe area between and mutually separating the number of die. The scribe area between at least two die of the number of die may include a test structure. The test structure may include a p-doped region and an n-doped region adjacent to the p-doped region. The test structure may also include a first contact electrically coupled to the p-doped region. The test structure may also include a second contact electrically coupled to the n-doped region and proximate to the first contact.

Additional embodiments of the present disclosure include a device including a number of p-doped regions extending in a first direction and a number of n-doped regions extending in the first direction, alternatingly arranged with the number of p-doped regions. The device may also include a first number of contacts electrically coupled to respective p-doped regions of the number of p-doped regions. The device may also include a second number of contacts electrically coupled to respective n-doped regions of the number of n-doped regions.

Additional embodiments of the present disclosure include a method including directing an electron-beam at a test structure in a scribe area of a wafer. The test structure may include a p-doped region and an n-doped region adjacent to the p-doped region. The test structure may also include a first contact electrically coupled to the p-doped region. The test structure may also include a second contact electrically coupled to the n-doped region and proximate to the first contact. The method may also include generating a reflection profile from the test structure responsive to the electron-beam indicative of electrons reflected by the first contact and the second contact. The method may also include determining a state of the test structure based on the reflection profile.

Additional embodiments of the present disclosure include a system for directing an electron-beam at a test structure in a scribe area of a wafer. The test structure may include a p-doped region and an n-doped region adjacent to the p-doped region. The test structure may also include a first contact electrically coupled to the p-doped region. The test structure may also include a second contact electrically coupled to the n-doped region and proximate to the first contact. The system may also generate a reflection profile from the test structure responsive to the electron-beam indicative of electrons reflected by the first contact and the second contact. The system may also determine a state of the test structure based on the reflection profile.

In accordance with common practice, the various features illustrated in the drawings may not be drawn to scale. The illustrations presented in the disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

As used herein, the term “device” or “memory device” may include a device with memory, but is not limited to a device with only memory. For example, a device or a memory device may include memory, a processor, and/or other components or functions. For example, a device or memory device may include a system on a chip (SOC).

As used herein, the term “semiconductor” should be broadly construed, unless otherwise specified, to include microelectronic and MEMS devices that may or may not employ semiconductor functions for operation (e.g., magnetic memory, optical devices, etc.).

As used herein, the term “substantially” in reference to a given parameter, property, or condition means and includes to a degree that one skilled in the art would understand that the given parameter, property, or condition is met with a small degree of variance, such as within acceptable manufacturing tolerances. For example, a parameter that is substantially met may be at least about 90% met, at least about 95% met, or even at least about 99% met.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

What is claimed is:

1. A device comprising:
a silicon wafer comprising:
a number of die; and
a scribe area between and mutually separating the number of die, the scribe area between at least two die of the number of die comprising a test structure comprising:
a p-doped region;
an n-doped region adjacent to the p-doped region;
a first contact electrically coupled to the p-doped region; and
a second contact electrically coupled to the n-doped region and proximate to the first contact.

2. The device of claim 1, wherein the p-doped region extends in a first direction, wherein the n-doped region extends in the first direction alongside the p-doped region, and wherein the test structure further comprises:
a third contact electrically coupled to the p-doped region and separate from the first contact in the first direction; and
a fourth contact electrically coupled to the n-doped region and proximate to the third contact.

3. The device of claim 2, wherein the test structure further comprises a buffer between the first contact and the third contact and between the second contact and the fourth contact.

4. The device of claim 1, wherein the p-doped region is a first p-doped region that extends in a first direction, wherein the n-doped region is a first n-doped region that extends in the first direction alongside the first p-doped region, and wherein the test structure further comprises:
a second p-doped region extending in the first direction alongside the first n-doped region;
a second n-doped region extending in the first direction alongside the second p-doped region;
a third contact electrically coupled to the second p-doped region; and
a fourth contact electrically coupled to the second n-doped region and proximate to the third contact.

5. The device of claim 1 wherein the n-doped region comprises a first n-doped region and wherein the test structure further comprises a second n-doped region under the p-doped region.

6. The device of claim 1 wherein the n-doped region comprises a first n-doped region and wherein the test structure further comprises a second n-doped region at least partially under the p-doped region and the first n-doped region.

7. The device of claim 1, wherein the wafer further comprises a substrate in which the p-doped region and the n-doped region are arranged, the substrate being p-doped.

8. The device of claim 1, wherein the p-doped region comprises a first p-doped region, and wherein the test structure further comprises a second p-doped region under the first p-doped region and the n-doped region.

9. The device of claim 1, wherein the test structure further comprises a buffer region between the p-doped region and the n-doped region.

10. A device comprising:
a number of p-doped regions extending in a first direction;
a number of n-doped regions extending in the first direction, alternatingly arranged with the number of p-doped regions;
a first number of contacts electrically coupled to respective p-doped regions of the number of p-doped regions; and
a second number of contacts electrically coupled to respective n-doped regions of the number of n-doped regions.

11. The device of claim 10, wherein the first number of contacts are distributed in the first direction along each of the number of p-doped regions and wherein the second number of contacts are distributed in the first direction along each of the number of n-doped regions.

12. The device of claim 11, wherein each of the first number of contacts is aligned, in the first direction, with a respective contact of the second number of contacts.

13. The device of claim 12, further comprising a buffer between pairs of aligned contacts.

14. The device of claim 10, wherein the number of n-doped regions comprises a first number of n-doped regions and wherein the device further comprises a second number of n-doped regions, each of the second number of n-doped regions under a respective p-doped region of the number of p-doped regions.

15. The device of claim 10, further comprising an n-doped region under the number of p-doped regions and the number of n-doped regions.

16. The device of claim 10, further comprising a substrate in which the number of p-doped regions and the number of n-doped regions are arranged, the substrate being p-doped.

17. The device of claim 10, further comprising a p-doped region under the number of p-doped regions and the number of n-doped regions.

18. The device of claim 10, further comprising a number of buffer regions, each of the number of buffer regions between a respective one of the number of p-doped regions and one of the number of n-doped regions.

19. A method comprising:
directing an electron-beam at a test structure in a scribe area of a wafer, the test structure comprising:
a p-doped region;
an n-doped region adjacent to the p-doped region;
a first contact electrically coupled to the p-doped region; and
a second contact electrically coupled to the n-doped region and proximate to the first contact;
generating a reflection profile from the test structure responsive to the electron-beam indicative of electrons reflected by the first contact and the second contact; and
determining a state of the test structure based on the reflection profile.

20. The method of claim 19, wherein determining the state of the test structure comprises:
determining that the test structure exhibits a contact-to-contact leak responsive to a count of electrons reflected by the second contact exceeding a threshold; or
determining that the test structure does not exhibit the contact-to-contact leak responsive to the count not exceeding the threshold.

21. The method of claim 19, wherein:
the test structure further comprises:
a number of p-doped regions extending in a first direction, the number of p-doped regions comprising the p-doped region;
a number of n-doped regions extending in the first direction, the number of n-doped regions alternatingly arranged with the number of p-doped regions, the number of n-doped regions comprising the n-doped region;
a first number of contacts electrically coupled to respective p-doped regions of the number of p-doped regions, the first number of contacts distributed in the first direction along each of the number of p-doped regions, the first number of contacts comprising the first contact; and
a second number of contacts electrically coupled to respective n-doped regions of the number of n-doped regions, the second number of contacts distributed in the first direction along each of the number of n-doped regions, the second number of contacts comprising the second contact; and
further comprising:
generating the reflection profile comprises generating the reflection profile indicative of electrons reflected by each of the first number of contacts and each of the second number of contacts; and
determining a state of the test structure comprises determining an error rate based on a count of the second number of contacts that exhibit reflectivity in the reflection profile.
